(19) United States
(12) Patent Application Publication
(10) Pub. No.: US 2010/0144096 A1
(43) Pub. Date: Jun. 10, 2010

(54) METHOD OF MANUFACTURING SEMICONDUCTOR DEVICE IN WHICH BOTTOM SURFACE AND SIDE SURFACE OF SEMICONDUCTOR SUBSTRATE ARE COVERED WITH RESIN PROTECTIVE FILM

(75) Inventors: Taisuke Koroku, Sagamihara-shi (JP); Osamu Okada, Hamura-shi (JP); Osamu Kuwabara, Tokyo (JP); Junji Shiota, Hamura-shi (JP); Nobumitsu Fujii, Ome-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignees: Casio Computer Co., Ltd., Tokyo (JP); EPAS

(21) Appl. No.: 12/632,033

(22) Filed: Dec. 7, 2009

(30) Foreign Application Priority Data
Dec. 9, 2008 (JP) 2008-313220

(51) Int. Cl. H01L 21/60

(52) U.S. Cl. 438/113; 257/E21.508

(57) ABSTRACT

First, a trench is formed in parts of a semiconductor wafer, a sealing film and other elements corresponding to a dicing street and both sides thereof. In this state, the semiconductor wafer is separated into silicon substrates by the formation of the trench. Then, a resin protective film is formed on the bottom surface of each silicon substrate including the inner part of the trench. In this case, the semiconductor wafer is separated into the silicon substrates. However, a support plate is affixed to the upper surfaces of the columnar electrode and the sealing film via an adhesive layer. Therefore, when the resin protective film is formed, it is possible to prevent the entire workpiece including the separated silicon substrates from being easily warped.

### CROSS-REFERENCE TO RELATED APPLICATIONS

This application is based upon and claims the benefit of priority from prior Japanese Patent Application No. 2008-313220, filed Dec. 9, 2008, the entire contents of which are incorporated herein by reference.

### BACKGROUND OF THE INVENTION

1. Field of the Invention

The present invention relates to a method of manufacturing a semiconductor device in which the bottom surface and side surface of a semiconductor substrate are covered with a resin protective film.

2. Description of the Related Art

A device which is called a chip-size package (CSP) is known from Published Japanese Patent No. 4103896. In this semiconductor device, a plurality of wiring lines are provided on the upper surface of an insulating film disposed on a semiconductor substrate. A columnar electrode is provided on the upper surface of a connection pad portion of the wiring line. A sealing film is provided on the upper surface of the insulating film including the wiring lines so that the upper surface of this sealing film is flush with the upper surface of the columnar electrode. A solder ball is provided on the upper surface of the columnar electrode. In this case, in order to prevent the exposure of the lower surface and side surface of the semiconductor substrate, the lower surface and side surface of the semiconductor substrate are covered with a resin protective film.

Meanwhile, in Published Japanese Patent No. 4103896, an assembly in which an insulating film, wiring lines, columnar electrodes and a sealing film are formed is prepared on the upper side of a semiconductor substrate in a wafer state (hereinafter referred to as a semiconductor wafer). Then, the semiconductor wafer is inverted. Then, a trench having a predetermined width is formed partway through the sealing film by half-cut (cutting halfway) between semiconductor device formation regions on the bottom side (surface opposite to that on which the sealing film and other elements are formed) of the semiconductor wafer. In this state, the semiconductor wafer is separated into semiconductor substrates by the formation of the trench.

Furthermore, a resin protective film is formed on the bottom surfaces of the semiconductor substrates including the inner part of the trench. Then, the entire workpiece including the semiconductor substrates is inverted. Then, solder balls are formed on the upper surfaces of the columnar electrodes. Then, the sealing film and the protective film are cut in the center of the width direction of the trench. Consequently, a semiconductor device having a structure wherein the bottom surface and side surface of the semiconductor substrate are covered with the resin protective film is obtained.

However, in Published Japanese Patent No. 4103896, after the trench is formed partway through the sealing film by half-cut on the bottom side of the inverted semiconductor wafer, the resin protective film is simply formed on the bottom surfaces of the semiconductor substrates including the inner part of the trench. That is, the resin protective film is simply formed in a condition where the semiconductor wafer is separated into the semiconductor substrates by the formation of the trench. Therefore, strength in the half-cut step and the subsequent steps decreases, and the entire workpiece including the semiconductor substrates is warped to a relatively great extent. This disadvantageously causes difficulty in maintaining the quality and in handling in each step.

### BRIEF SUMMARY OF THE INVENTION

It is an object of this invention to provide a semiconductor device manufacturing method which can prevent the entire workpiece including semiconductor substrates from being easily warped during the formation of a resin protective film for protecting the semiconductor substrates.

According to a first aspect of the present invention, there is provided a semiconductor device manufacturing method comprising: preparing an assembly having an insulating film formed on one surface of a semiconductor wafer where an integrated circuit is formed, an electrode connection pad portion formed on the insulating film in such a manner as to be connected to the integrated circuit, an external connection bump electrode formed on the electrode connection pad portion, and a sealing film formed around the external connection bump electrode; affixing a support plate to the external connection bump electrode and the sealing film; forming a trench reaching an intermediate position of the thickness of the sealing film on the bottom side of the semiconductor wafer in parts corresponding to a dicing street and both sides thereof; forming a resin protective film on the bottom surface of the semiconductor wafer including the inner part of the trench; peeling off the support plate; and cutting the sealing film and the resin protective film in a width smaller than the width of the trench, wherein a plurality of semiconductor devices are obtained in which the protective resin film is formed on a side surface ranging from the side surface of the semiconductor substrate to the intermediate position of the sealing film and on the bottom surface of the semiconductor substrate.

According to this invention, a resin protective film is formed on the bottom surface of a semiconductor wafer (semiconductor substrates) including the inner part of a trench in a condition where a support plate is affixed to an external connection bump electrode and a sealing film. Thus, it is possible to prevent the entire workpiece including the semiconductor substrates from being easily warped during the formation of the resin protective film for protecting the semiconductor substrates.

### BRIEF DESCRIPTION OF THE SEVERAL VIEWS OF THE DRAWING

FIG. 1 is a sectional view of one example of a semiconductor device manufactured by a manufacturing method of this invention;

FIG. 2 is a sectional view of an initially prepared assembly in one example of the method of manufacturing the semiconductor device shown in FIG. 1;

FIG. 3 is a sectional view of a step following FIG. 2;

FIG. 4 is a sectional view for explaining an adhesive layer shown in FIG. 3;

FIG. 5 is a sectional view of a step following FIG. 3;

FIG. 6 is a sectional view of a step following FIG. 5;

FIG. 7 is a sectional view of a step following FIG. 6;

FIG. 8 is a sectional view of a step following FIG. 7;

FIG. 9 is a sectional view of a step following FIG. 8;

FIG. 10 is a sectional view of a step following FIG. 9;

FIG. 11 is a sectional view of a step following FIG. 10;

FIG. 12 is a sectional view of a step following FIG. 11;

FIG. 13 is a sectional view of a step following FIG. 12; and

FIG. 14 is a sectional view of a step following FIG. 13.

### DETAILED DESCRIPTION OF THE INVENTION

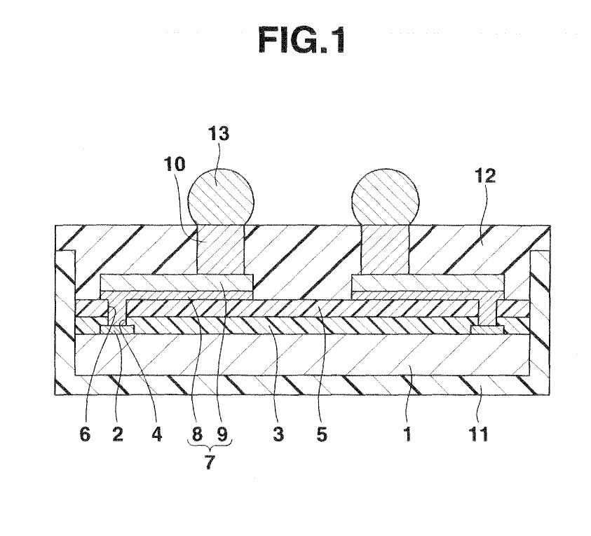

FIG. 1 shows a sectional view of one example of a semiconductor device manufactured by a manufacturing method of this invention. This semiconductor device is generally called a CSP, and includes a silicon substrate (semiconductor substrate) 1. Elements (not shown) constituting an integrated circuit having a predetermined function, such as a transistor, a diode, a register and a condenser, are formed on the upper surface of the silicon substrate 1. Connection pads 2 made of, for example, an aluminum-based metal and connected to the elements of the integrated circuit are provided in the peripheral part of the upper surface of the silicon substrate 1. Although only two connection pads 2 are shown, a large number of connection pads 2 are actually arranged on the peripheral part of the upper surface of the silicon substrate 1.

A passivation film (insulating film) 3 consisting of, for example, silicon oxide is provided on the upper surfaces of the silicon substrate 1 except for the center of the connection pad 2. The center of the connection pad 2 is exposed via an opening 4 provided in the passivation film 3. A protective film (insulating film) 5 consisting of, for example, a polyimide-based resin is provided on the upper surface of the passivation film 3. An opening 6 is provided in a part of the protective film 5 corresponding to the opening 4 of the passivation film 3.

An interconnect 7 is provided on the upper surface of the protective film 5. The interconnect 7 has a two-layer structure composed of a metal foundation layer 8 of, for example, copper provided on the upper surface of the protective film 5, and an upper metal layer 9 of copper provided on the upper surface of the metal foundation layer 8. One end of the wiring line 7 is connected to the connection pad 2 via the openings 4, 6 of the passivation film 3 and the upper protective film 5. A columnar electrode (external connection bump electrode) 10 made of copper is provided on the upper surface of a connection pad portion (electrode connection pad portion) of the wiring line 7.

A resin protective film 11 consisting of, for example, epoxy resin is provided on the bottom surface of the silicon substrate 1 and on the side surfaces of the silicon substrate 1, the passivation film 3 and the upper protective film 5. In this case, the upper part of the resin protective film 11 provided on the side surfaces of the silicon substrate 1, the passivation film 3 and the upper protective film 5 projects straight upward from the upper surface of the upper protective film 5. In this state, the lower surface of the silicon substrate 1 and the side surfaces of the silicon substrate 1, the passivation film 3 and the upper protective film 5 are covered with the resin protective film 11.

A sealing film 12 consisting of, for example, epoxy resin is provided on the upper surface of the upper protective film 5 including the interconnect 7 and on the upper surface of the resin protective film 11 therearound. The columnar electrode 10 is provided so that its upper surface is flush with or several μm lower than the upper surface of the sealing film 12. A solder ball 13 is provided on the upper surface of the columnar electrode 10.

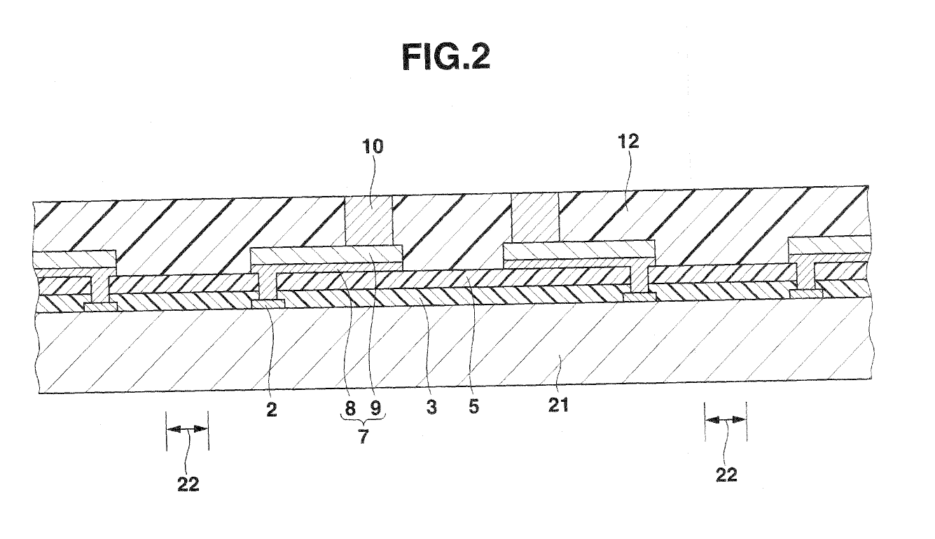

Next, one example of a method of manufacturing this semiconductor device is described. First, as shown in FIG. 2, an assembly in which a connection pad 2, a passivation film 3, a protective film 5, a wiring line 7 having a two-layer structure composed of a metal foundation layer 8 and an upper metal layer 9, a columnar electrode 10 and a sealing film 12 are provided is prepared on a silicon substrate in a wafer state (hereinafter referred to as a semiconductor wafer 21). Such a method of manufacturing the semiconductor wafer 21 is already known. For details, see, for example, FIG. 2 to FIG. 7 and relevant parts in the specification of Japanese Patent No. 3955059.

In this case, the thickness of the semiconductor wafer 21 is greater to some degree than the thickness of the silicon substrate 1 shown in FIG. 1. Moreover, the upper surface of the sealing film 12 including the upper surface of the columnar electrode 10 is planar. Here, a zone indicated by the sign 22 in FIG. 2 is a zone corresponding to the dicing street.

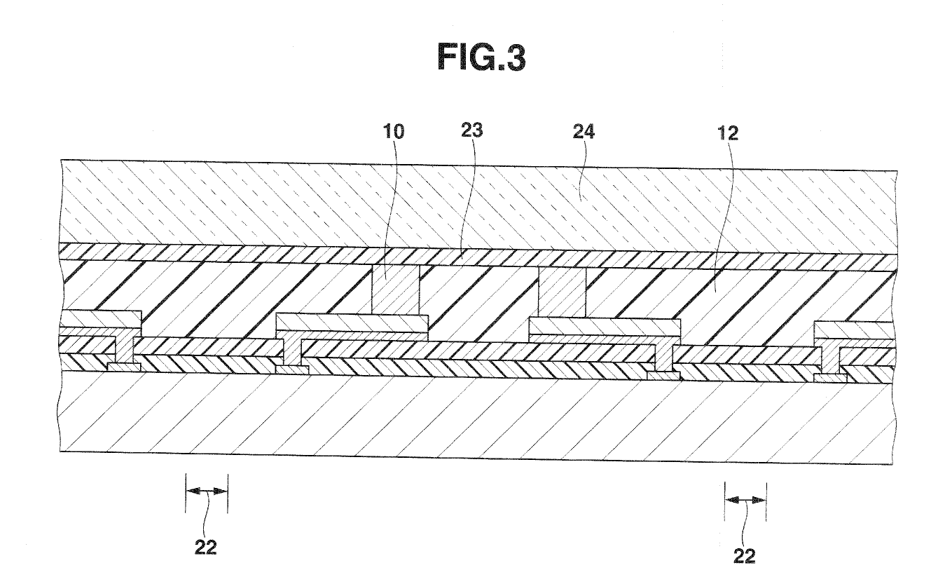

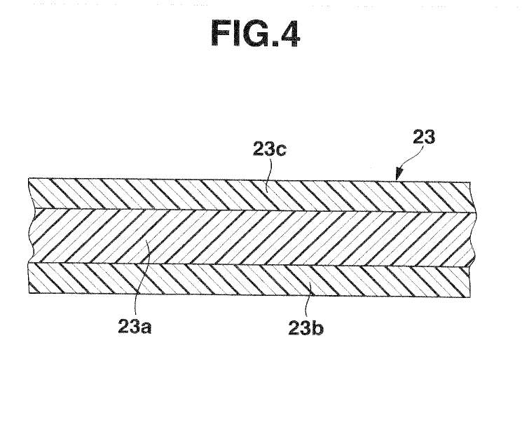

Now, when the assembly shown in FIG. 2 is prepared, a support plate 24 is affixed to the upper surfaces of the columnar electrode 10 and the sealing film 12 via an adhesive layer 23, as shown in FIG. 3. In this case, to be specific, the cohesive layer 23 is what is generally called a double-sided adhesive tape in which a cohesive agent is provided on two sides of a base material film, as shown in FIG. 4. The cohesive layer 23 has a structure wherein an ultraviolet-curable lower cohesive agent 23b in an uncured state is provided on the lower surface of a base material film 23a and wherein an ultraviolet-sensitive gas-generating upper cohesive agent 23c in an uncured state is provided on the upper surface of the base material film 23a (e.g., Selfa adhesive tape manufactured by Sekisui Chemical Co., Ltd.).

The upper cohesive agent 23c and the lower cohesive agent 23b consist of a material which has cohesive properties at room temperature but is cured by ultraviolet radiation and thus decreases its bonding force and becomes detachable. In particular, the upper cohesive agent 23c contains a gas-generating agent which generates a gas in response to ultraviolet radiation, details of which will be given later. Although not shown, a detachment tape is affixed to the lower surface of the lower cohesive agent 23b and the upper surface of the upper cohesive agent 23c in the initial cohesive layer 23. The support plate 24 is a hard plate having the property of transmitting ultraviolet rays, such as a circular glass plate, which is slightly larger than the semiconductor wafer 21.

Then, the detachment tape on the side of the lower cohesive agent 23h of the cohesive layer 23 is first detached, and the lower cohesive agent 23b of the cohesive layer 23 is affixed to the upper surfaces of the columnar electrode 10 and the sealing film 12. Then, under vacuum, the detachment tape on the side of the upper cohesive agent 23c of the cohesive layer 23 is detached, and the support plate 24 made of, for example, glass is affixed to the upper surface of the upper cohesive agent 23c of the cohesive layer 23. The support plate 24 is affixed under vacuum to prevent air from being contained between the support plate 24 and the upper cohesive agent 23c of the cohesive layer 23.

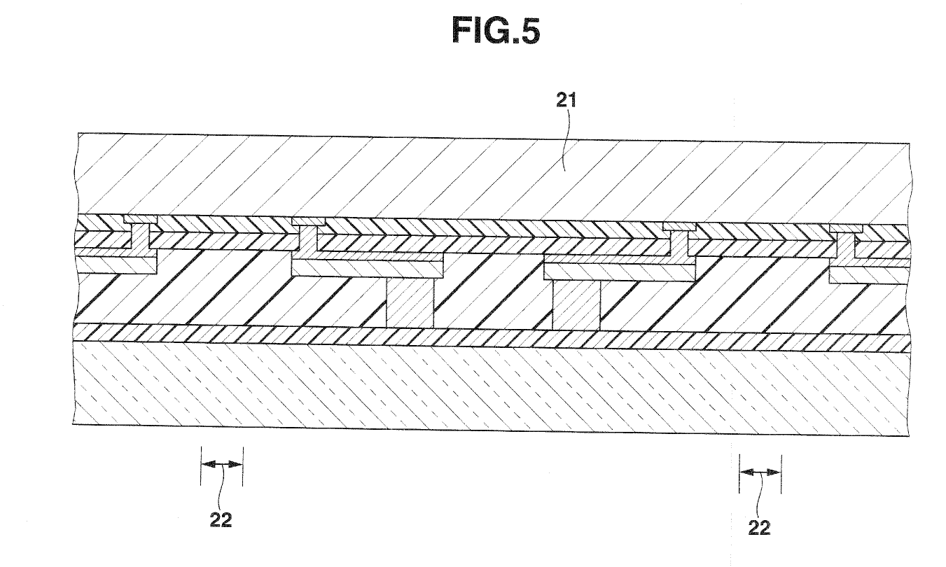

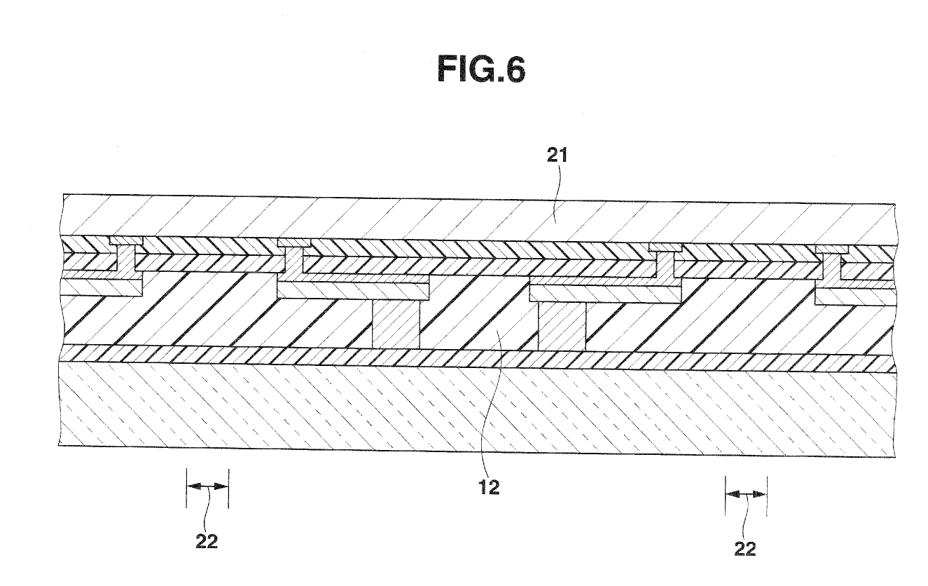

Then, the assembly shown in FIG. 3 is inverted to turn up the bottom surface (surface opposite to that on which the sealing film 12 and other elements are formed) of the semiconductor wafer 21, as shown in FIG. 5. Then, as shown in FIG. 6, the bottom side of the semiconductor wafer 21 is properly ground using a grindstone (not shown) to properly reduce the thickness of the semiconductor wafer 21. In addition, the support plate 24 may be affixed after the thickness of the semiconductor wafer 21 is properly reduced.

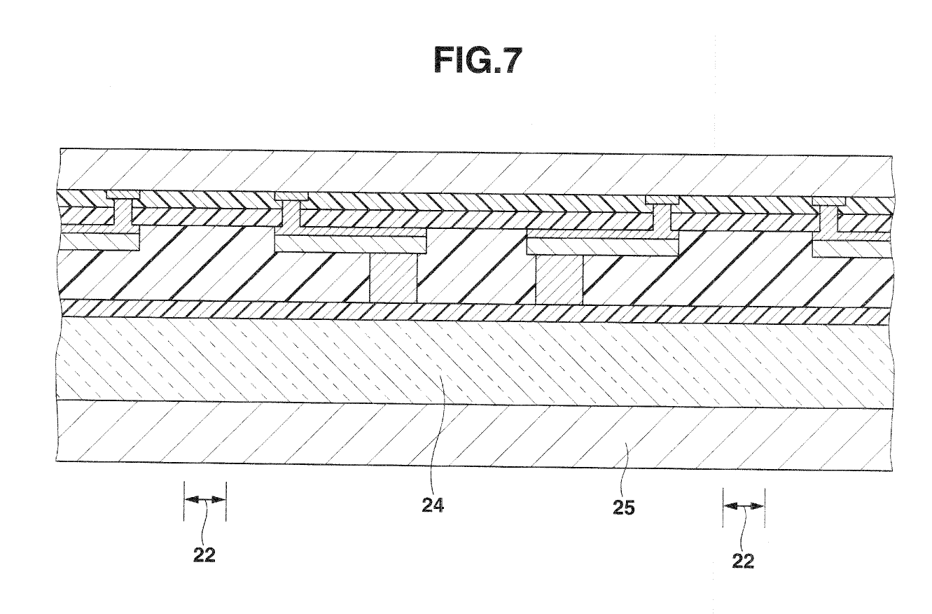

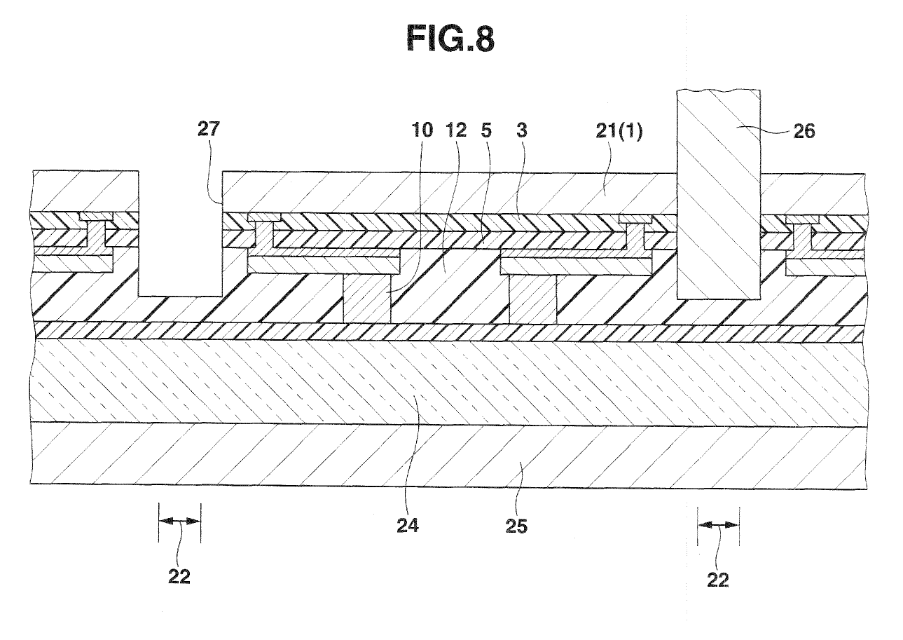

Then, as shown in FIG. 7, the lower surface of the support plate 24 is affixed to the upper surface of a dicing tape 25. Then, as shown in FIG. 8, a blade 26 is prepared. This blade 26 is a disk-shaped grindstone. The sectional shape of its edge is substantially U-shaped, and its thickness is greater to some degree than the width of the dicing street 22.

Furthermore, this blade 26 is used to form a trench 27 in parts of the semiconductor wafer 21 corresponding to the dicing street 22 and both sides thereof, the passivation film 3, the protective film 5 and the sealing film 12. In this case, the depth of the trench 27 extends partway in the sealing film 12, and is, for example, ½ or more, preferably ⅓ or more than the thickness of the sealing film 12. In this state, the semiconductor wafer 21 is separated into the semiconductor substrates 1 by the formation of the trench 23. Then, the support plate 24 is detached from the upper surface of the dicing tape 26. In addition, in this step, the use of a dicing machine for the half-cut enables processing without affixing the dicing tape.

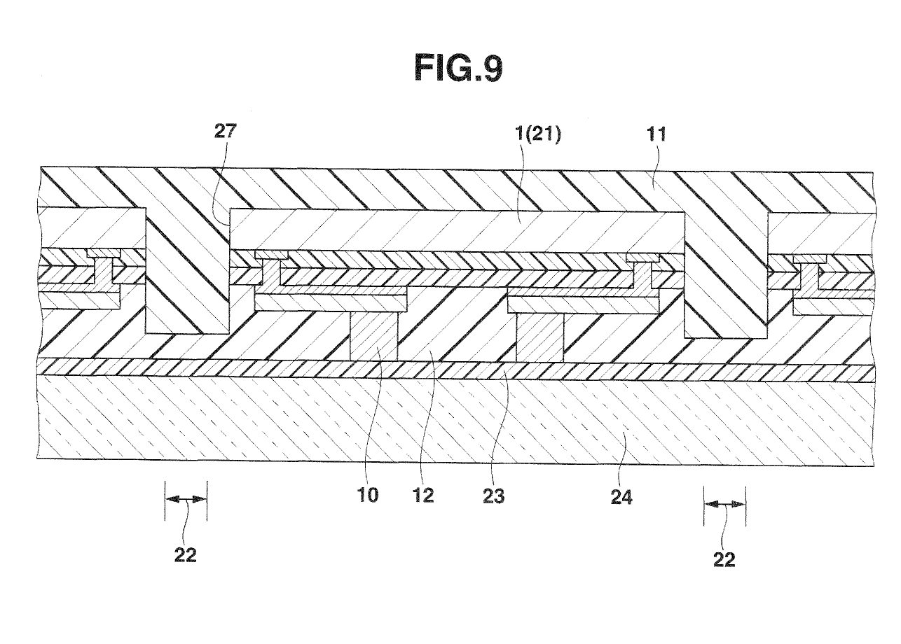

Then, as shown in FIG. 9, a thermosetting resin such as epoxy resin is applied to the bottom side of the silicon substrate 1 including the inner part of the trench 27 by, for example, the spin coating or screen printing method. The thermosetting resin is cured to form the resin protective film 11. The curing temperature of the resin protective film 11 ranges from 120 to 180° C. in consideration of the thermal resistance of the ultraviolet-curable lower cohesive agent 23b (see FIG. 4), and the processing time is 1 to 2 hours.

In this case, the semiconductor wafer 21 is separated into the silicon substrates 1. However, the support plate 24 is affixed to the lower surfaces of the columnar electrode 10 and the sealing film 12 via the adhesive layer 23. Therefore, when the trench 27 is formed and when the resin protective film 11 consisting of a thermosetting resin such as epoxy resin is applied and cured, it is possible to prevent the entire workpiece including the separated silicon substrates 1 from being easily warped, and it is also possible to prevent any difficulty from being caused in the subsequent steps by the warping.

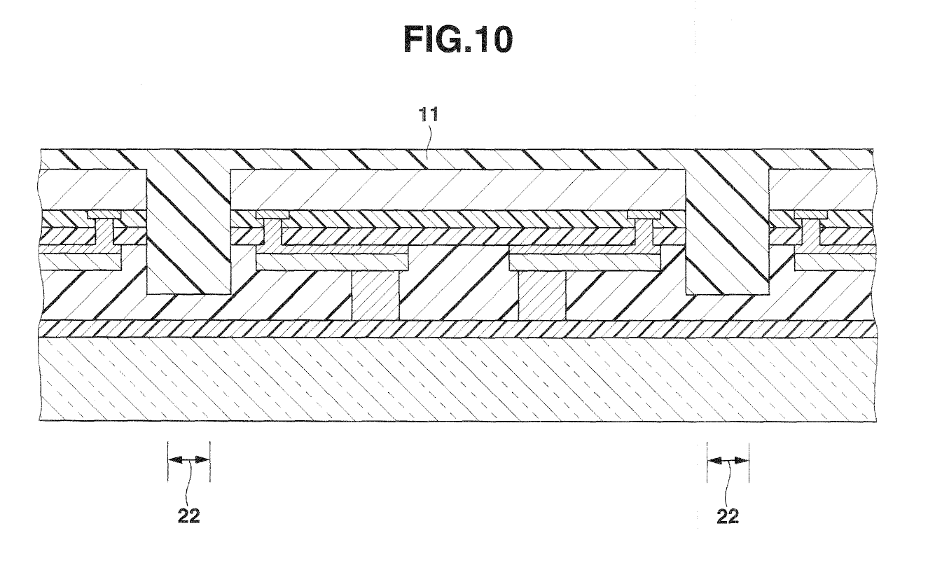

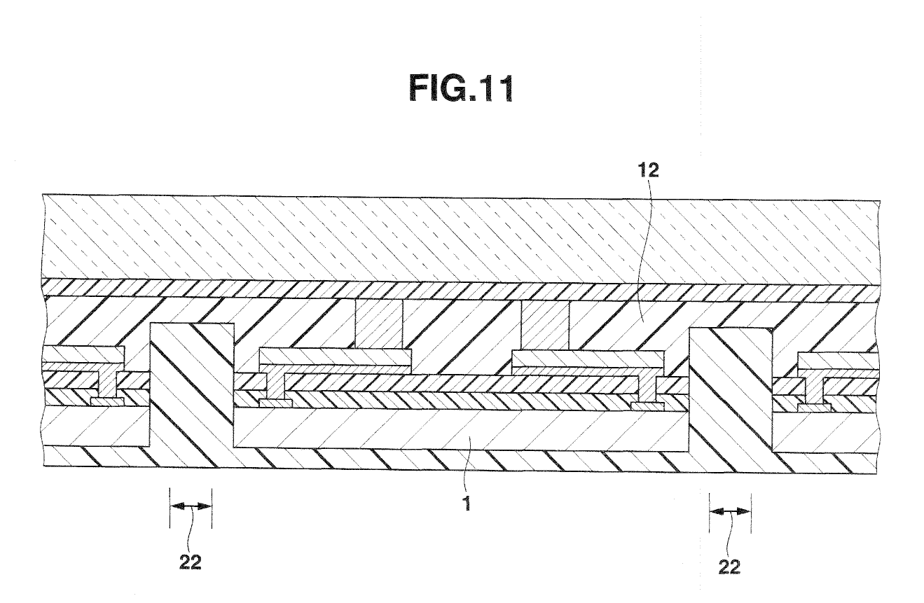

Then, as shown in FIG. 10, the upper side of the resin protective film 11 is properly ground using a grindstone (not shown) to properly reduce the thickness of the resin protective film 11 and to planarize the upper surface of the resin protective film 11. This grinding step is performed to further reduce the thickness of the semiconductor device. Then, the assembly shown in FIG. 10 is inverted to turn up the side of the silicon substrate 1 where the sealing film 12 and other elements are formed, as shown in FIG. 11.

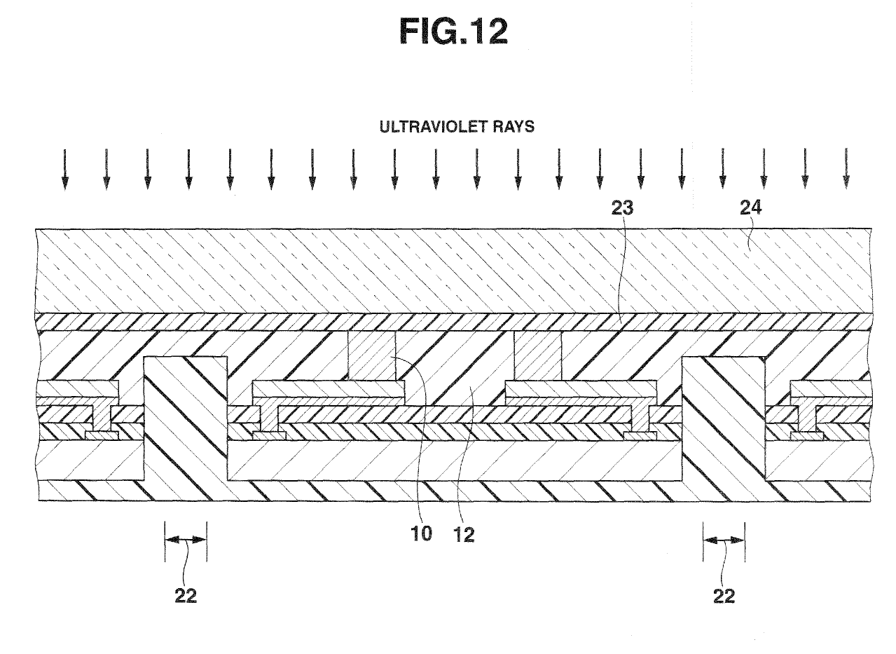

Then, as shown in FIG. 12, ultraviolet rays are radiated from above the support plate 24. The ultraviolet-sensitive gas-generating upper cohesive agent 23c (see FIG. 4) of the cohesive layer 23 contains the gas-generating agent which generates a gas in response to ultraviolet radiation. Thus, a gas is generated from the upper cohesive agent 23c, and the upper surface of the upper cohesive agent 23c becomes uneven. As a result, a bonding interface between the upper cohesive agent 23c and the support plate 24 decreases, and bonding force is reduced, so that the support plate 24 can be detached from the upper cohesive agent 23c of the cohesive layer 23. Such a cohesive agent containing the gas-generating agent which generates a gas in response to ultraviolet radiation is described in Jpn. Pat. Appln. KOKAI Publication No. 2005-294536. The upper cohesive agent 23c is called a self-detaching adhesive agent in that it can detach on its own by generating the gas. Moreover, the ultraviolet-curable lower cohesive agent 23b (see FIG. 4) of the cohesive layer 23 is cured, and the bonding force between the lower cohesive agent 23b and the columnar electrode 10 as well as the sealing film 12. Therefore, the cohesive layer 23 is then detached from the upper surfaces of the columnar electrode 10 and the sealing film 12.

Here, the reason that the upper cohesive agent 23c of the cohesive layer 23 is an ultraviolet-sensitive gas-generating type and that the lower cohesive agent 23b is an ultraviolet-curable type is described. The support plate 24 made of, for example, glass is not flexible, so that its region corresponding to the whole surface of the semiconductor wafer has to be detached at once. In other words, the support plate 24 can not be peeled off little by little. Therefore, it is not possible to separate the support plate 24 and the silicon substrate 1 from each other without deformation or damage. Thus, the upper cohesive agent 23c is formed as the ultraviolet-sensitive gas-generating type to facilitate the detachment of the support plate 24. Then, the cohesive layer 23 is sufficiently flexible and can therefore be easily peeled off. Thus, the lower cohesive agent 23b is formed as the ultraviolet-curable type.

Only the ultraviolet-curable lower cohesive agent 23b is coated on (one side of) the support plate 24 (where it contacts with the sealing film 12). Then, the support board 2 and the silicon substrate 1 are under pressure when pealing off each other because these are hard, and it is possible to crack the support board 24 and the silicon substrate 1.

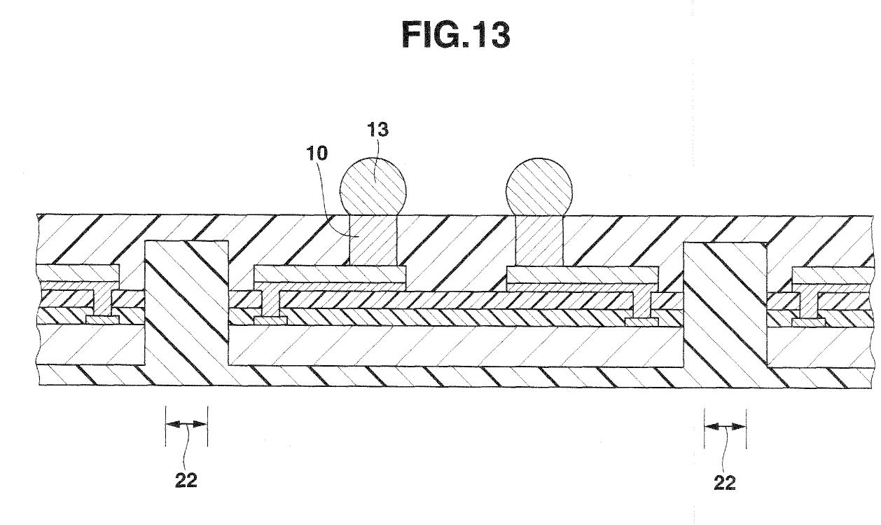

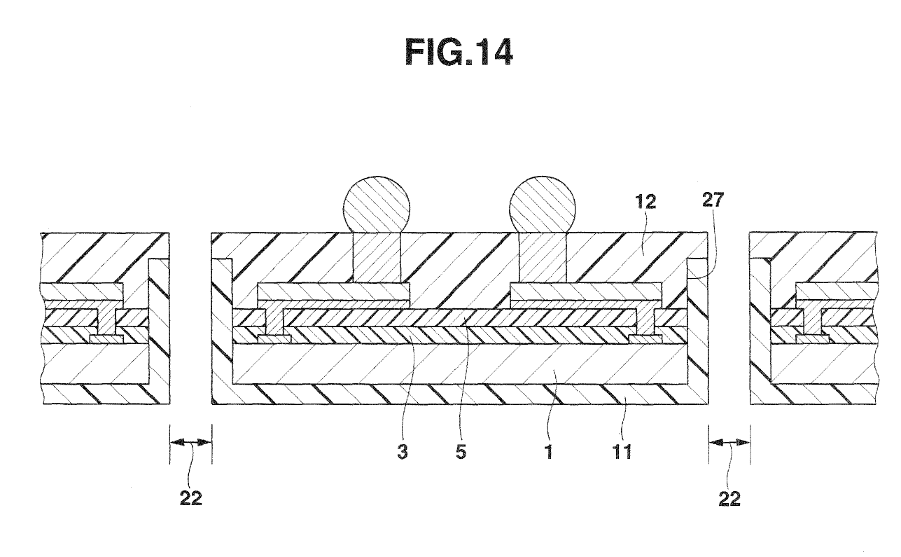

Therefore, the ultraviolet-sensitive gas-generating upper cohesive agent 23c can be used because it can float up when pealing. Moreover, it becomes easily reusable by the peel of the tape if it makes it to the method to do tape the cohesive layer 23 to the support board 24 in the laminate. However, if only the lower cohesive agent 23b is spread on the support board 24, recycling the support hoard 24 becomes difficult. Then, as shown in FIG. 13, a solder ball 13 is formed on the upper surface of the columnar electrode 10. In this case, if a burr and an oxide film are formed on the upper surface of the columnar electrode 10, the upper surface of the columnar electrode 10 is etched several μm to remove the burr and oxide film. Then, as shown in FIG. 14, the sealing film 12 and the protective resin film 11 are cut along the dicing street 22 in the center of the trench 28.

In this case, a blade having the same width as the width of the dicing street 22 is used. Therefore, as shown in FIG. 14, the sealing film 12 is cut so that its side surface is formed to extend from the intermediate position of the protective resin film 11 which is provided on the side surfaces of the silicon substrate 1, the passivation film 3, the protective film 5 and the sealing film 12 up to the intermediate position of the sealing film 12. Consequently, as shown in FIG. 1, a plurality of semiconductor devices having a structure wherein the bottom surface and side surface of the silicon substrate 1 are covered with the protective resin film 11 are obtained.

In addition, in the embodiment described above, the double-sided adhesive tape is used as the material of the adhesive layer, and this double-sided adhesive tape has, on one surface, a cohesive agent which generates a gas in response to ultraviolet radiation and thus decreases its bonding strength, and has, on the other surface, a cohesive agent. However, various modifications can be made to the material of the adhesive layer. For example, a nonaqueous high molecular compound is used as the adhesive layer, and a material having a large number of pores is used as the support plate, so that a detachment solution can be infiltrated from the large number of pores to separate the support plate. Alternatively, a material which is thermally decomposed by the radiation of laser light and thereby becomes detachable can be used as the adhesive layer. Moreover, a hard plate such as a laser transmitting glass plate can be used as the support plate.

What is claimed is:

1. A semiconductor device manufacturing method comprising:
preparing an assembly having an insulating film formed on one surface of a semiconductor wafer where an integrated circuit is formed, an electrode connection pad portion formed on the insulating film in such a manner as to be connected to the integrated circuit, an external connection bump electrode formed on the electrode connection pad portion, and a sealing film formed around the external connection bump electrode;
affixing a support plate to the external connection bump electrode and the sealing film;
forming a trench reaching an intermediate position of the thickness of the sealing film on the bottom side of the semiconductor wafer in parts corresponding to a dicing street and both sides thereof;
forming a resin protective film on the bottom surface of the semiconductor wafer including the inner part of the trench;
peeling off the support plate; and
cutting the sealing film and the resin protective film in a width smaller than the width of the trench.

2. The semiconductor device manufacturing method according to claim 1, wherein affixing the support plate includes affixing the support plate to the external connection bump electrode and the sealing film via a cohesive layer, and detaching the support plate includes detaching the cohesive layer.

3. The semiconductor device manufacturing method according to claim 2, wherein the cohesive layer consists of a double-sided adhesive tape wherein an ultraviolet-curable cohesive agent is provided on a surface of a base material film where the external connection bump electrode and the sealing film are affixed and wherein an ultraviolet-sensitive gas-generating cohesive agent is provided on the other surface of the base material film.

4. The semiconductor device manufacturing method according to claim 3, wherein the support plate is made of glass.

5. The semiconductor device manufacturing method according to claim 4, wherein detaching the support plate and the cohesive layer includes radiating ultraviolet rays from the side of the support plate.

6. The semiconductor device manufacturing method according to claim 5, wherein detaching the support plate and the cohesive layer includes detaching the cohesive layer after detaching the support plate.

7. The semiconductor device manufacturing method according to claim 6, wherein forming the resin protective film on the bottom surface of the semiconductor wafer includes curing the resin protective film at 120 to 180° C.

8. The semiconductor device manufacturing method according to claim 2, wherein the bottom side of the semiconductor wafer is ground to reduce the thickness of the semiconductor wafer after or before the support plate is affixed.

9. The semiconductor device manufacturing method according to claim 2, further comprising grinding the upper side of the resin protective film to reduce the thickness of the resin protective film and planarize the upper surface of the resin protective film, after the resin protective film is formed.

10. The semiconductor device manufacturing method according to claim 2, wherein the external connection bump electrode is a columnar electrode formed on the electrode connection pad portion.

11. The semiconductor device manufacturing method according to claim 2, further comprising forming a solder ball on the columnar electrode after the resin protective film is formed.
